(19) United States
(12) Patent Application Publication
(10) Pub. No.: US 2024/0168084 A1
(43) Pub. Date: May 23, 2024

(54) SEMICONDUCTOR STRUCTURE

(71) Applicant: United Microelectronics Corp., Hsinchu (TW)

(72) Inventors: Jih-Shun Chiang, Hsinchu City (TW); Wen-Chun Chang, Hsinchu City (TW); Wen-Hsiung Ko, Taichung City (TW); Sung-Nien Kuo, New Taipei City (TW); Kuan-Cheng Su, Taipei (TW)

(73) Assignee: United Microelectronics Corp., Hsinchu (TW)

(21) Appl. No.: 18/085,560

(22) Filed: Dec. 20, 2022

(30) Foreign Application Priority Data
Nov. 18, 2022 (TW) 111144163

(51) Int. Cl. G01R 31/28; H01L 23/34; H01L 23/528; H01L 23/532

(52) U.S. Cl. CPC G01R 31/2875; H01L 23/345; H01L 23/5283; H01L 23/53223; H01L 23/5329

(57) ABSTRACT

A semiconductor structure is provided. The semiconductor structure includes at least one metal gate structure and a device to be tested. The metal gate structure is disposed on a substrate. The device to be tested is disposed on the metal gate structure and electrically separated from the metal gate structure. The device to be tested is heated by a heat generated when the metal gate structure is applied with a voltage.

### CROSS-REFERENCE TO RELATED APPLICATION

This application claims the priority benefit of Taiwan application serial no. 111144163, filed on Nov. 18, 2022. The entirety of the above-mentioned patent application is hereby incorporated by reference herein and made a part of this specification.

### BACKGROUND

### Technical Field

The present invention relates to a semiconductor structure, and particularly to a semiconductor structure in which the metal gate structure may be used as a heater to heat a device to be tested.

### Description of Related Art

In the current semiconductor process, when the reliability of a device is to be evaluated, the wafer is usually placed on an external heater for heating. In this way, the ambient temperature around the device to be tested and the temperature of the device to be tested may be increased to be suitable for a reliability test. However, it often takes too much time for the external heater to heat the wafer and the efficiency of heat conduction is not good, thus increasing the time-consuming of the reliability evaluation. In addition, placing the wafer on the external heater for heating also increases the probability of damage to the wafer during moving the wafer.

### SUMMARY

The present invention provides a semiconductor structure in which the metal gate structure is used as a heater to heat the device to be tested.

The semiconductor structure of the present invention includes at least one metal gate structure and a device to be tested. The metal gate structure is disposed on a substrate. The device to be tested is disposed on the metal gate structure and electrically separated from the metal gate structure. The device to be tested is heated by a heat generated when the metal gate structure is applied with a voltage.

In an embodiment of the semiconductor structure of the present invention, a line width of a metal gate of the metal gate structure does not exceed 2 μm.

In an embodiment of the semiconductor structure of the present invention, a resistance of a metal gate of the metal gate structure is at least 3000 ohm.

In an embodiment of the semiconductor structure of the present invention, from a top view on the substrate, the metal gate structure has a mesh shape on the substrate.

In an embodiment of the semiconductor structure of the present invention, from a top view on the substrate, the metal gate structure has a curved line shape on the substrate.

In an embodiment of the semiconductor structure of the present invention, the at least one metal gate structure includes a plurality of strip-shaped metal gate structures, and the plurality of strip-shaped metal gate structures are electrically connected to each other.

In an embodiment of the semiconductor structure of the present invention, the metal gate structure includes a gate dielectric layer and a work-function metal layer disposed on the substrate in sequence.

In an embodiment of the semiconductor structure of the present invention, the metal gate structure includes the gate dielectric layer, a bottom barrier layer, the work-function metal layer, a top barrier layer and a low-resistance metal layer disposed on the substrate in sequence.

In an embodiment of the semiconductor structure of the present invention, a material of the gate dielectric layer includes hafnium oxide.

In an embodiment of the semiconductor structure of the present invention, a material of the bottom barrier layer includes TaN, TiN or a combination thereof.

In an embodiment of the semiconductor structure of the present invention, a material of the work-function metal layer includes TiAl, TiN or a combination thereof.

In an embodiment of the semiconductor structure of the present invention, a material of the top barrier layer includes TiN.

In an embodiment of the semiconductor structure of the present invention, a material of the low-resistance metal layer includes Al.

In an embodiment of the semiconductor structure of the present invention, the heat generated when the metal gate structure is applied with the voltage increases an ambient temperature of the device to be tested to 200° C. to 400° C.

In an embodiment of the semiconductor structure of the present invention, the device to be tested includes a circuit pattern layer.

In an embodiment of the semiconductor structure of the present invention, the semiconductor structure further includes an interconnect structure disposed between the metal gate structure and the device to be tested, wherein the interconnect structure is electrically separated from the metal gate structure and the device to be tested.

Based on the above, in the present invention, the metal gate structure as a heater is disposed under the device to be tested to heat the environment around the device to be tested and the device to be tested. In this way, when testing the reliability of the device to be tested, it is not necessary to place the wafer on an external heater for heating in advance, so the in-line monitoring may be achieved, the damage to the wafer during moving the wafer may be avoided, and the time spent on reliability evaluation may be effectively shorten.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic cross-sectional view of the semiconductor structure of the embodiment of the present invention.

FIG. 1B is a schematic top view of the metal gate structure on the substrate in FIG. 1A.

FIG. 1C is a schematic cross-sectional view of a detailed structure of the metal gate structure in FIG. 1A.

FIG. 1D is a schematic cross-sectional view of another detailed structure of the metal gate structure in FIG. 1A.

FIGS. 2 to 4 are schematic top views of the metal gate structure located on the substrate in different embodiments of the present invention, respectively.

FIG. 5 is a schematic cross-sectional view of the semiconductor structure of another embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

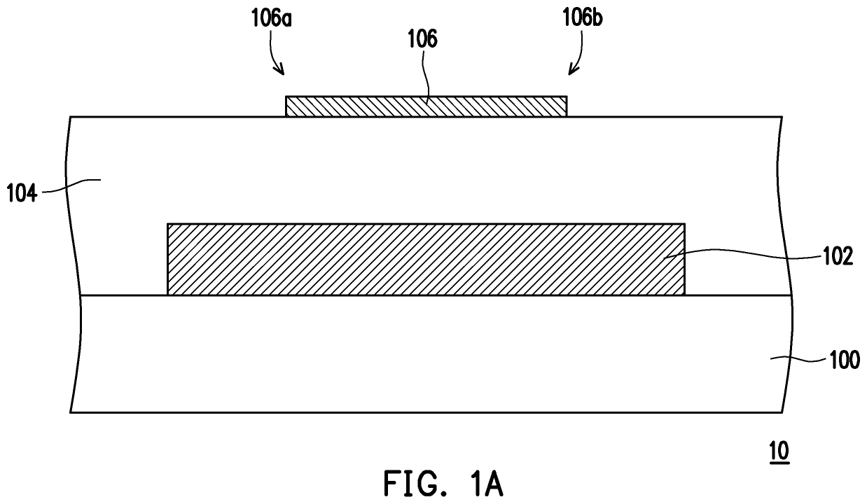

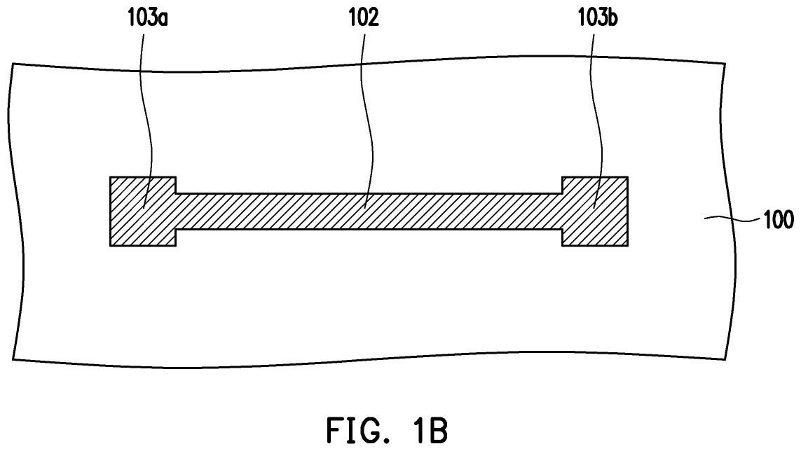

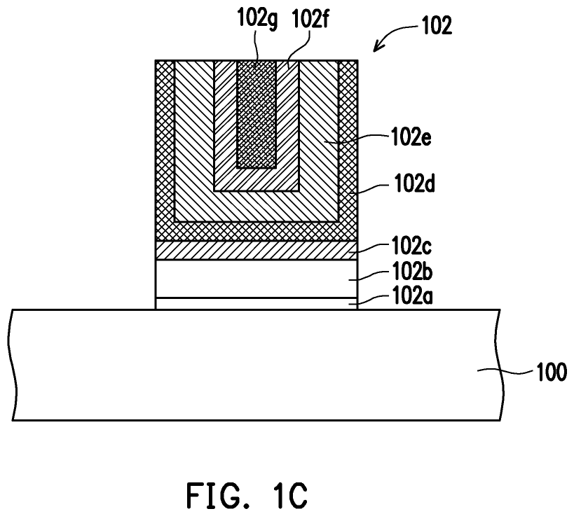

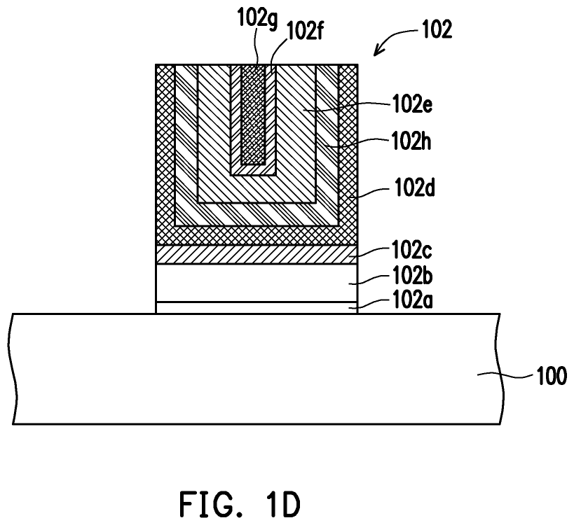

FIG. 1A is a schematic cross-sectional view of the semiconductor structure of the embodiment of the present invention. FIG. 1B is a schematic top view of the metal gate structure on the substrate in FIG. 1A. Referring to FIG. 1A, the semiconductor structure 10 of the present embodiment includes a substrate 100, a metal gate structure 102, a dielectric layer 104 and a device to be tested 106. In FIG. 1A, in order to make the drawing clear and easy to describe, the detailed structure of the metal gate structure 102 is not shown, which will be described later. In the present embodiment, the substrate 100 is, for example, a silicon substrate or a silicon-on-insulator (SOI) substrate. The metal gate structure 102 disposed on substrate 100. Furthermore, in the present embodiment, the metal gate structure 102 has a stripe pattern. As shown in FIG. 1B, from the top view of the substrate 100, the metal gate structure 102 is strip-shaped on the substrate 100 and has a first terminal 103a and a second terminal 103b, but the present invention is not limited thereto.

In the present embodiment, the metal gate structure 102 includes a gate dielectric layer and a work-function metal layer disposed on the substrate 100 in sequence. Additionally, the metal gate structure 102 may have any other desired components. For example, in an embodiment, as shown in FIG. 1C, the metal gate structure 102 may include a gate dielectric layer 102a, a gate dielectric layer 102b, a bottom barrier layer 102c, a bottom barrier layer 102d, a work-function metal layer 102e, a top barrier layer 102f and a low-resistance metal layer 102g disposed on the substrate 100 in sequence. The material of the gate dielectric layer 102a may be silicon oxide, and the gate dielectric layer 102a may have a thickness of about 10 Å. The material of the gate dielectric layer 102b may be a well-known high dielectric constant material, such as hafnium oxide, and the gate dielectric layer 102b may have a thickness of about 10 Å. That is, the gate dielectric layer of the metal gate structure 102 may be a composite dielectric layer, but the present invention is not limited thereto. In other embodiments, the gate dielectric layer of the metal gate structure 102 may have a single-layer structure. The material of the bottom barrier layer 102c may be TiN, and the bottom barrier layer 102c may have a thickness of about 20 Å. The material of the bottom barrier layer 102d may be TaN, and the bottom barrier layer 102d may have a thickness of about 20 Å. That is, the bottom barrier layer of the metal gate structure 102 may have a composite structure, but the present invention is not limited thereto. In other embodiments, the bottom barrier layer of the metal gate structure 102 may have a single-layer structure. The work-function metal layer 102e is surrounded by the bottom barrier layer 102d. The material of the work-function metal layer 102e may be TiAl, and the work-function metal layer 102e may have a thickness of about 100 Å. The top barrier layer 102f is surrounded by the work-function metal layer 102e. The material of the top barrier layer 102f may be TiN, and the top barrier layer 102f may have a thickness of about 40 Å. The low-resistance metal layer 102g is surrounded by the top barrier layer 102f. The material of the low-resistance metal layer 102g may be a commonly known low-resistance metal material, such as Al. In addition, the top surface of the bottom barrier layer 102d, the top surface of the work-function metal layer 102e, the top surface of the top barrier layer 102f and the top surface of the low-resistance metal layer 102g are substantially coplanar. In the above structure, the bottom barrier layer 102c, the bottom barrier layer 102d, the work-function metal layer 102e, the top barrier layer 102f and the low-resistance metal layer 102g may be regarded as the metal gate of the metal gate structure 102. The total thickness of the gate dielectric layer 102b and the metal gate is preferably not more than 1000 Å.

In another embodiment, as shown in FIG. 1D, the metal gate structure 102 may include a gate dielectric layer 102a, a gate dielectric layer 102b, a bottom barrier layer 102c, a bottom barrier layer 102d, a work-function metal layer 102h, a work-function metal layer 102e, a top barrier layer 102f and a low-resistance metal layer 102g sequentially disposed on the substrate 100. The material of the gate dielectric layer 102a may be silicon oxide, and the gate dielectric layer 102a may have a thickness of about 10 Å. The material of the gate dielectric layer 102b may be a well-known high dielectric constant material, such as hafnium oxide, and the gate dielectric layer 102b may have a thickness of about 10 Å. That is, the gate dielectric layer of the metal gate structure 102 may be a composite dielectric layer, but the present invention is not limited thereto. In other embodiments, the gate dielectric layer of the metal gate structure 102 may have a single-layer structure. The material of the bottom barrier layer 102c may be TiN, and the bottom barrier layer 102c may have a thickness of about 20 Å. The material of the bottom barrier layer 102d may be TaN, and the bottom barrier layer 102d may have a thickness of about 20 Å. That is, the bottom barrier layer of the metal gate structure 102 may have a composite structure, but the present invention is not limited thereto. In other embodiments, the bottom barrier layer of the metal gate structure 102 may have a single-layer structure. The work-function metal layer 102h is surrounded by the bottom barrier layer 102d. The material of the work-function metal layer 102h may be TiN, and the work-function metal layer 102h may have a thickness of about 50 Å. The work-function metal layer 102e is surrounded by the work-function metal layer 102h. The material of the work-function metal layer 102e may be TiAl, and the work-function metal layer 102e may have a thickness of about 100 Å. That is, the work-function metal layer of the metal gate structure 102 may have a composite structure. The top barrier layer 102f is surrounded by the work-function metal layer 102e. The material of the top barrier layer 102f may be TiN, and the top barrier layer 102f may have a thickness of about 40 Å. The low-resistance metal layer 102g is surrounded by a top barrier layer 102f. The material of the low-resistance metal layer 102g may be a commonly known low-resistance metal material, such as Al. In addition, the top surface of the bottom barrier layer 102d, the top surfaces of the work-function metal layer 102h, the top surfaces of the work-function metal layer 102e, the top surfaces of the barrier layer 102f and the top surfaces of the low-resistance metal layer 102g are substantially coplanar. In addition, the bottom barrier layer 102c, the bottom barrier layer 102d, the work-function metal layer 102h, the work-function metal layer 102e, the top barrier layer 102f and the low-resistance metal layer 102g may be regarded as the metal gate of the metal gate structure 102. The total thickness of the gate dielectric layer 102b and the metal gate is preferably not more than 1000 Å.

Based on the above, the metal gate structure 102 is basically composed of a gate dielectric layer and a metal gate disposed on the gate dielectric layer. In the present embodiment, the line width of the metal gate of the metal gate structure 102 does not exceed 2 μm. When the line width of the metal gate of the metal gate structure 102 exceeds 2 μm, a recess may occur at the top surface of the metal gate, which is generally called dishing. The dishing of the metal gate leads to non-uniform thickness of the metal gate, so that the heating effect of the metal gate structure 102 which is applied with a voltage to the device to be tested 106 is affected.

In addition, in the present embodiment, the resistance of the metal gate of the metal gate structure 102 is at least 3000 ohm. In this way, after the metal gate structure 102 is applied with a voltage, the metal gate structure 102 may effectively heat the ambient temperature around the device to be tested 106 and the temperature of the device to be tested 106 to 200° C. to 400° C.

The dielectric layer 104 is disposed on the substrate 100 and covers the metal gate structure 102. The device to be tested 106 is disposed on dielectric layer 104. In the present embodiment, the device to be tested 106 is a circuit pattern layer. Generally speaking, the circuit pattern layer is a metal layer, so the device to be tested 106 may be regarded as the first layer of metal layer, usually also called metal 1, in the semiconductor structure 10. In the present embodiment, there is no contact between the device to be tested 106 and the metal gate structure 102. That is, the device to be tested 106 and the metal gate structure 102 are electrically separated. The device to be tested 106 has a first terminal 106a and a second terminal 106b. By applying the voltage(s) to the first terminal 106a and/or the second terminal 106b, a required electrical test may be performed to evaluate the reliability of the device to be tested 106. The electrical test may be an electromigration (EM) test.

For the semiconductor structure 10, when evaluating the reliability of the device to be tested 106, the metal gate structure 102 is used as a heater to heat the environment around the device to be tested 106 and the device to be tested 106, so that the ambient temperature around the device to be tested 106 and the temperature of the device to be tested 106 are heated to 200° C. to 400° C.

In detail, the voltages may be applied to the first terminal 103a and the second terminal 103b of the metal gate structure 102, so that the current flows through the entire metal gate of the metal gate structure 102 to generate heat, and the generated heat may be transferred to the environment around the device to be tested 106 and the device to be tested 106. Since the line width of the metal gate of the metal gate structure 102 is not more than 2 μm and the resistance of the metal gate of the metal gate structure 102 is at least 3000 ohm, the metal gate may quickly generate heat, and the ambient temperature of the device to be tested 106 and the temperature of the device to be tested 106 may be rapidly raised to 200° C. to 400° C. In this way, the electromigration test may be directly performed on the device to be tested 106 without additionally placing the wafer including the semiconductor structure 10 on an external heater for heating. As a result, the on-line monitoring may be achieved and the damage to the wafer during moving the wafer may be avoided, and the time spent on reliability evaluation may be effectively shorten.

In the above embodiment, from the top view on the substrate 100, the metal gate structure 102 is strip-shaped on the substrate 100, and only one metal gate structure 102 is disposed on the substrate 100, but the present invention is not limited thereto. In other embodiments, the metal gate structure 102 may have other shapes on the substrate 100, and a plurality of the metal gate structures 102 may be disposed on the substrate 100.

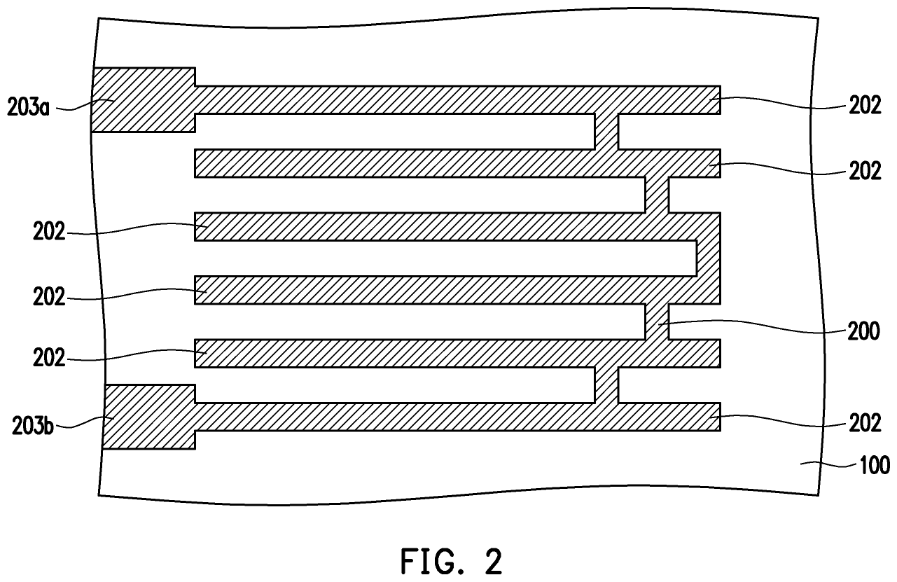

FIGS. 2 to 4 are schematic top views of the metal gate structure located on the substrate in different embodiments of the present invention, respectively.

As shown in FIG. 2, from the top view of the substrate 100, strip-shaped metal gate structures 202 are disposed parallel to each other on the substrate 100, and the metal gate structures 202 are electrically connected to each other through connect structures 200. In the present embodiment, the connect structure 200 may be a portion extending from the metal gate structure 202, but the present invention is not limited thereto. The detailed structure of the metal gate structure 202 may be the same as that of the metal gate structure 102, and will not be further described here. In this way, the metal gate structures 202 may work together as a heater, and the resistance value of the heater is effectively increased. Voltages may be applied to the metal gate structures 202 through a first terminal 203a and a second terminal 203b, so that the current may flow through the metal gates of the metal gate structures 202 to generate heat.

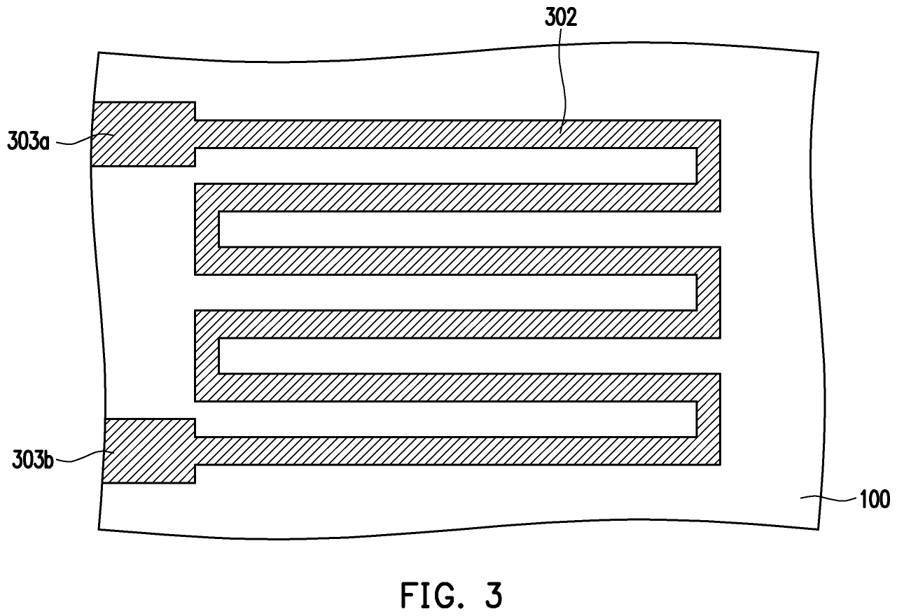

As shown in FIG. 3, from the top view of the substrate 100, a metal gate structure 302 is disposed on the substrate 100, and the metal gate structure 302 is in the shape of a curved line on the substrate 100. The detailed structure of the metal gate structure 302 may be the same as that of the metal gate structure 102, and will not be further described here. In this way, the resistance value of the heater is effectively increased by increasing the conductive path of the metal gate structure. Voltages may be applied to the metal gate structure 302 through a first terminal 303a and a second terminal 303b, so that the current may flow through the metal gate of the metal gate structure 302 to generate heat.

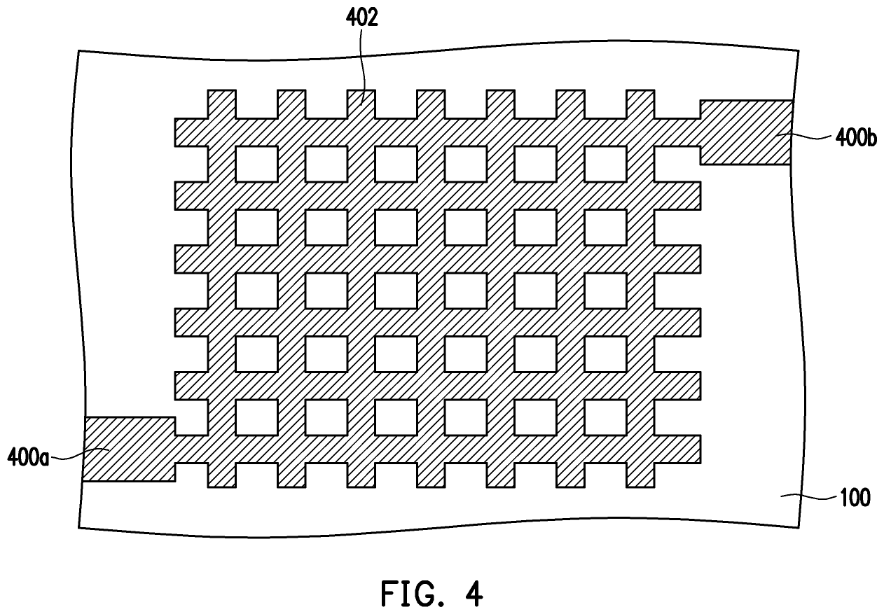

As shown in FIG. 4, from the top view of the substrate 100, a metal gate structure 402 is disposed on the substrate 100, and the metal gate structure 402 is in a mesh shape on the substrate 100. The detailed structure of the metal gate structure 402 may be the same as that of the metal gate structure 102, and will not be further described here. In this way, the resistance value of the heater is effectively increased by increasing the conductive path and layout area of the metal gate structure. Voltages may be applied to the metal gate structure 402 through a first terminal 400a and a second terminal 400b, so that the current may flow through the metal gate of 402 to generate heat.

In addition, in the above embodiments, the device to be tested 106 is the first metal layer (metal 1) in the semiconductor structure, but the present invention is not limited thereto. Among other embodiments, the device to be tested 106 may be the metal layer of other layers in the semiconductor structure.

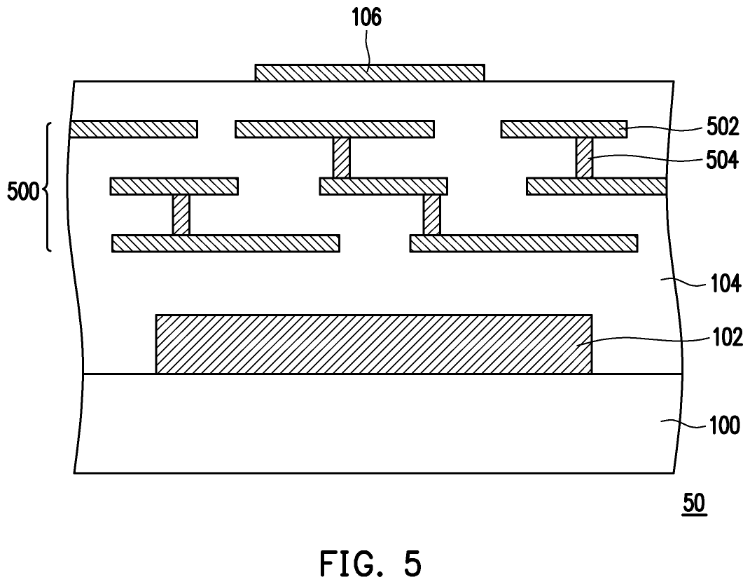

FIG. 5 is a schematic cross-sectional view of the semiconductor structure of another embodiment of the present invention. In the present embodiment, the same devices as in FIG. 1A will be denoted by the same reference numbers, and will not be described again.

Referring to FIG. 5, in the present embodiment, the difference between the semiconductor structure 50 and the semiconductor structure 10 is that: in the semiconductor structure 50, an interconnect structure 500 is disposed in dielectric layer 104, and the interconnect structure 500 is electrically separated from the metal gate test structure 102 and the device to be 106. In detail, the interconnect structure 500 includes three layers of circuit layers 502, and two adjacent layers of the circuit layers 502 are electrically connected to each other through conductive vias 504. In addition, there is no contact between the interconnect structure 500 and the metal gate structure 102, and there is no conductive via between the interconnect structure 500 and the device to be tested 106. In the present embodiment, since the circuit layers 502 are metal layers, the interconnect structure 500 includes three layers of metal layers, usually called metal 1, metal 2 and metal 3, and the device to be tested 106 may be regarded as the fourth layer of metal layer, usually called metal 4.

For the semiconductor structure 50, when the reliability evaluation of the test device to be tested 106 is to be performed, the voltages may be applied to the metal gate structure 102, so that the current may flow through the entire metal gate of the metal gate structure 102 to generate heat, and the generated heat may be transferred to the interconnect structure 500. In the interconnect structure 500, since the three layers of circuit layers 502 are connected to each other through the conductive vias 504, the heat may be quickly transferred from the lower layer to the upper layer, so as to heat the environment around the device to be tested 106 disposed above the interconnect structure 500 and the device to be tested 106, and the temperature may be raised to 200° C. to 400° C.

In the present embodiment, the interconnect structure 500 includes three layers of circuit layer 502 and conductive vias 504, but the present invention is not limited thereto. In other embodiments, the interconnect structure may include other numbers of circuit layers or other devices depending on actual needs.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
at least one metal gate structure, disposed on a substrate; and
a device to be tested, disposed on the metal gate structure, and electrically separated from the metal gate structure,
wherein the device to be tested is heated by a heat generated when the metal gate structure is applied with a voltage.

2. The semiconductor structure of claim 1, wherein a line width of a metal gate of the metal gate structure does not exceed 2 μm.

3. The semiconductor structure of claim 1, wherein a resistance of a metal gate of the metal gate structure is at least 3000 ohm.

4. The semiconductor structure of claim 1, wherein from a top view on the substrate, the metal gate structure has a mesh shape on the substrate.

5. The semiconductor structure of claim 1, wherein from a top view on the substrate, the metal gate structure has a curved line shape on the substrate.

6. The semiconductor structure of claim 1, wherein the at least one metal gate structure comprises a plurality of strip-shaped metal gate structures, and the plurality of strip-shaped metal gate structures are electrically connected to each other.

7. The semiconductor structure of claim 1, wherein the metal gate structure comprises a gate dielectric layer and a work-function metal layer disposed on the substrate in sequence.

8. The semiconductor structure of claim 7, wherein the metal gate structure comprises the gate dielectric layer, a bottom barrier layer, the work-function metal layer, a top barrier layer and a low-resistance metal layer disposed on the substrate in sequence.

9. The semiconductor structure of claim 8, wherein a material of the gate dielectric layer comprises hafnium oxide.

10. The semiconductor structure of claim 8, wherein a material of the bottom barrier layer comprises TaN, TiN or a combination thereof.

11. The semiconductor structure of claim 8, wherein a material of the work-function metal layer comprises TiAl, TiN or a combination thereof.

12. The semiconductor structure of claim 8, wherein a material of the top barrier layer comprises TiN.

13. The semiconductor structure of claim 8, wherein a material of the low-resistance metal layer comprises Al.

14. The semiconductor structure of claim 1, wherein the heat generated when the metal gate structure is applied with the voltage increases an ambient temperature of the device to be tested to 200° C. to 400° C.

15. The semiconductor structure of claim 1, wherein the device to be tested comprises a circuit pattern layer.

16. The semiconductor structure of claim 1, further comprising an interconnect structure disposed between the metal gate structure and the device to be tested, wherein the interconnect structure is electrically separated from the metal gate structure and the device to be tested.
